(19) United States
(12) Patent Application Publication
(10) Pub. No.: US 2023/0303455 A1
(43) Pub. Date: Sep. 28, 2023

(54) CERAMIC SUBSTRATE, ALN SINGLE CRYSTAL, ALN WHISKER, AND ALN WHISKER COMPOSITE

(71) Applicant: U-MAP Co., Ltd., Aichi (JP)

(72) Inventors: Masaki Matsumoto, Aichi (JP); Shota Watanabe, Aichi (JP); Kenji Nishitani, Aichi (JP); Takahiro Maeda, Aichi (JP); Masashi Nagaya, Aichi (JP)

(21) Appl. No.: 17/928,253

(22) PCT Filed: Aug. 6, 2021
(86) PCT No.: PCT/JP2021/029410

§ 371 Date: Nov. 28, 2022

(30) Foreign Application Priority Data
Aug. 7, 2020 (JP) 2020-134777

(51) Int. Cl. C04B 35/80

(52) U.S. Cl. CPC C04B 35/80; C04B 2235/524; C04B 2235/9607; C04B 2235/963; C04B 2235/767

(57) ABSTRACT

Provided is a ceramic substrate having novel characteristics, capable of achieving thermal conductivity equal to or higher than that of a conventional ceramic substrate containing a granular aluminum nitride polycrystal in a base body thereof, and achieving fracture toughness superior to that of a conventional ceramic substrate containing a granular silicon nitride polycrystal in a base body thereof.

A ceramic substrate according to the present embodiment contains a fibrous AlN single crystal.

### TECHNICAL FIELD

The present embodiment relates to a ceramic substrate constituting a control module, for example, for industrial equipment. Further, the present embodiment relates to an AlN single crystal, an AlN whisker, and an AlN whisker composite contained in the ceramic substrate.

### BACKGROUND ART

A control module for performing power control or motor control of, for example, an electric vehicle, a self-driving vehicle, a railway, a machine tool, a data center, a high-luminance LED, or the like is a module to which a high voltage is applied, and a ceramic substrate is used as a substrate thereof. Also, various improvements have been attempted for this type of ceramic substrate. (See, for example, Patent Literature 1.)

### CITATION LIST

### Patent Literature

Patent Literature 1: JP 2007-63042 A

### SUMMARY OF INVENTION

### Technical Problem

The ceramic substrate used for the control module as described above is required to have high heat dissipation performance, and accordingly, there has been a demand for an improvement in thermal conductivity of the ceramic substrate itself. Also, a control module using a ceramic substrate repeats a high-temperature and low-temperature cycle. Therefore, in order to prevent a crack due to thermal stress in such a cycle, the ceramic substrate used for the control module is also required to have high mechanical strength. As described above, the ceramic substrate used for the control module is required to have both high thermal conductivity and high mechanical strength. Currently, ceramic substrates containing granular SiN polycrystals in their base bodies and ceramic substrates containing granular AlN polycrystals in their base bodies are mainly used in the market. The ceramic substrate using a granular SiN polycrystal in its base body has excellent fracture toughness but low thermal conductivity. On the other hand, the ceramic substrate using a granular AlN polycrystal in its base body has excellent thermal conductivity but low fracture toughness. As described above, the conventional ceramic substrates have advantages and disadvantages, and therefore, there is a demand for developing a ceramic substrate having both high thermal conductivity and high mechanical strength.

Accordingly, provided is a ceramic substrate having novel characteristics, capable of achieving thermal conductivity equal to or higher than that of a conventional ceramic substrate containing a granular aluminum nitride polycrystal in a base body thereof, and achieving fracture toughness superior to that of a conventional ceramic substrate containing a granular silicon nitride polycrystal in a base body thereof. Also, an AlN crystal, an AlN whisker, and an AlN whisker composite contained in the ceramic substrate are provided.

### Solution to Problem

A ceramic substrate according to the present embodiment contains a fibrous AlN single crystal in a base body thereof.

The ceramic substrate according to the present embodiment is capable of achieving higher thermal conductivity than a conventional ceramic substrate containing a granular AlN polycrystal, and further, achieving higher fracture toughness than a conventional ceramic substrate containing a granular SiN polycrystal. That is, it is possible to obtain a ceramic substrate having both high thermal conductivity and high mechanical strength.

### BRIEF DESCRIPTION OF DRAWINGS

FIG. 1 is a diagram schematically showing a configuration example of a power module according to the present embodiment.

FIG. 2 is a diagram showing characteristics of a ceramic substrate according to the present embodiment.

FIG. 3 is a perspective view schematically showing a structure of a fibrous AlN single crystal according to the present embodiment.

FIG. 4 is a diagram schematically showing a configuration example of a device for performing X-ray diffraction on the ceramic substrate according to the present embodiment and a structure example of the ceramic substrate.

FIG. 5 is a diagram showing an X-ray diffraction pattern for the ceramic substrate according to the present embodiment in comparison with that for a conventional ceramic substrate.

FIG. 6 is a diagram showing a correlation between a fracture toughness and an “a/c” value in the ceramic substrate according to the present embodiment.

FIG. 7 is a diagram showing a correlation between a fracture toughness and an amount of oxygen in the ceramic substrate according to the present embodiment.

FIG. 8 is a diagram showing a correlation between a thermal conductivity and an amount of oxygen in the ceramic substrate according to the present embodiment.

FIG. 9 is a diagram showing a microstructure of the ceramic substrate according to the present embodiment in comparison with that of a conventional ceramic substrate.

FIG. 10 is a diagram showing data regarding lengths and thicknesses of fibrous AlN single crystals contained in the ceramic substrate according to the present embodiment.

FIG. 11 is a diagram showing that a fibrous AlN single crystal of 100 μm or more exists in the structure of the ceramic substrate according to the present embodiment.

FIG. 12 is a diagram showing a fractured surface of the ceramic substrate according to the present embodiment in comparison with that of a conventional ceramic substrate.

FIG. 13 is a diagram showing a correlation between a fracture toughness and an arithmetic average roughness of a fractured surface in the ceramic substrate according to the present embodiment.

FIG. 14 is a diagram showing data regarding diameters and oxygen concentrations of AlN whiskers contained in the ceramic substrate according to the present embodiment.

### DESCRIPTION OF EMBODIMENTS

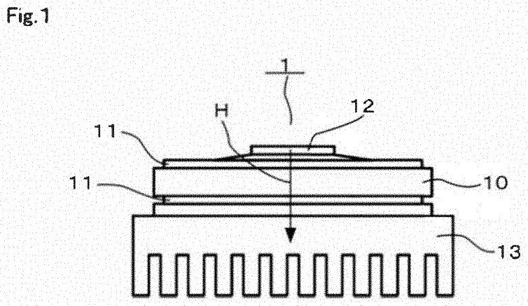

Hereinafter, an embodiment of a ceramic substrate will be described with reference to the drawings. A power module 1 shown in FIG. 1 is an example of a control module for performing power control or motor control of, for example, an electric vehicle, a self-driving vehicle, a railway, a machine tool, a data center, a high-luminance LED, or the like, and includes a ceramic substrate 10 according to the present embodiment. The ceramic substrate 10 is formed in a plate shape, and metal layers 11 are provided on both surfaces thereof in a plate thickness direction. Also, a so-called power semiconductor 12 is provided on one end surface of the ceramic substrate 10 in the plate thickness direction, in this case, an upper surface in FIG. 1. Also, a heat sink 13 having a heat dissipation function is provided on the other end surface of the ceramic substrate 10 in the plate thickness direction, in this case, a lower surface in FIG. 1.

As exemplified by an arrow H in FIG. 1, heat generated from the power semiconductor 12 is transmitted to the heat sink 13 via the ceramic substrate 10, thereby dissipating heat of the power module 1. Therefore, the ceramic substrate 10 is required to have a further improved thermal conductivity in its base body than a conventional ceramic substrate containing a granular AlN polycrystal. Also, for example, from the viewpoint of improvement in reliability, the ceramic substrate 10 is required to have a further improved fracture toughness, that is, a further improved mechanical strength, than a conventional ceramic substrate containing only a granular AlN polycrystal. The ceramic substrate 10 according to the present embodiment has been made to have inventiveness in improving both thermal conductivity and mechanical strength. Hereinafter, this point will be described in detail.

First, an example of a method for manufacturing the ceramic substrate 10 will be described. Steps for manufacturing the ceramic substrate 10 include a kneading step, a drying step, a granulating step, a molding step, a degreasing step, and a sintering step.

In the kneading step, fibrous AlN single crystals, that is, fibrous aluminum nitride single crystals, are put and dispersed in a mixed liquid of a known dispersion material containing an oil-and-fat component and an organic solvent. Thereafter, yttria as a sintering aid and granular AlN polycrystals, that is, aluminum nitride powders, are added and kneaded. As a result, a slurry is formed as a raw material of the ceramic substrate 10.

In the drying step, the slurry obtained in the kneading step is dried. The slurry is dried for a predetermined time, for example, about 1 hour, under the conditions of a temperature of 130° C. and a pressure of −0.1 MPa.

In the granulating step, a lump of slurry obtained in the drying step is loosened and rolled, for example, by a pod mill, to form the raw material into grains, that is, granulate the raw material.

In the molding step, the granular raw material obtained in the granulating step is put into a mold and pressed, for example, by a pressing machine. As a result, the raw material is formed into a plate shape.

In the degreasing step, the plate-shaped raw material obtained in the molding step is degreased. That is, the dispersion material is mainly removed from the raw material. The degreasing step is performed, for example, in a nitrogen atmosphere or in an air atmosphere. Also, the degreasing step is performed for a predetermined time, for example, about 4 to 6 hours under the condition of a temperature in the range of about 500 to 650 degrees.

In the sintering step, the plate-shaped raw material subjected to the degreasing step is sintered for a predetermined time, for example, about 1 hour, under the conditions of a temperature of 1900° C. and a pressure of 40 MPa.

Through the above-described steps, the ceramic substrate 10 containing fibrous AlN single crystals and granular AlN polycrystals in its base body can be manufactured. Additionally, the various conditions such as temperature, pressure, and time in each step described above can be appropriately changed when the step is performed. Also, the fibrous AlN single crystal refers to an AlN single crystal that is elongate in a fibrous form, and for example, may extend straight or partially curved or bent as long as it is fibrous as a whole.

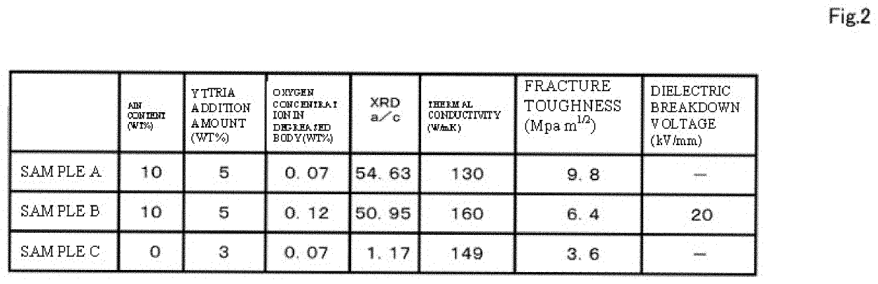

FIG. 2 shows characteristics of samples A and B from the ceramic substrate 10 obtained by the above-described manufacturing method. In both of the samples A and B, a fibrous AlN single crystal content is “10 wt %”, and an yttria addition amount is “5 wt %”. The samples A and B are different from each other in amount of oxygen contained in the plate-shaped raw material after the degreasing step described above.

Also, FIG. 2 shows characteristic values of sample C from a conventional ceramic substrate containing no fibrous AlN single crystal as a comparative example, together with characteristic values of the samples A and B from the ceramic substrate 10 obtained by the above-described manufacturing method. In the sample C, a fibrous AlN single crystal content is “0 wt %”, and an yttria addition amount is “3 wt %”.

As is clear from the characteristic values shown in FIG. 2, the sample B has a thermal conductivity of 150 W/mK or more, in this case, 160 W/mK. That is, the thermal conductivity of the sample B is higher than 149 W/mK, which is a thermal conductivity of the conventional sample C. Also, the thermal conductivity of the ceramic substrate 10 according to the present embodiment can be further improved, for example, through an annealing treatment after the sinter step. Also, the sample B has a fracture toughness of 4.0 MPam^{1/2} or more, in this case, 6.4 MPam^{1/2}. That is, the fracture toughness of the sample B is higher than 3.6 MPam^{1/2}, which is a fracture toughness of the conventional sample C. Also, the sample B has a dielectric breakdown voltage of 20 kV/mm. As described above, the ceramic substrate according to the present embodiment has a feature in that both thermal conductivity and fracture toughness are improved by introducing the fibrous AlN single crystal.

As described above, it has been confirmed that the above-described manufacturing method makes it possible to obtain a ceramic substrate 10 having an improved thermal conductivity and an improved fracture toughness as compared with a conventional ceramic substrate containing no fibrous AlN single crystal. Also, it has been confirmed that the above-described manufacturing method makes it possible to obtain a ceramic substrate 10 having a high dielectric breakdown voltage, i.e., 20 kV/mm.

In the present embodiment, a thermal conductivity is calculated based on values of thermal diffusivity, specific heat, and density. The thermal diffusivity was measured using a laser flash technique, for example, using “LFA501”, which is a device manufactured by Kyoto Electronics Manufacturing Co., Ltd, in accordance with “JIS R1603, Method for Measuring Thermal Diffusivity, Specific Heat Capacity and Thermal Conductivity of Fine Ceramics Based on Flash Technique”. The specific heat was measured using differential scanning calorimetry, for example, using “DSC-60A”, which is a device manufactured by Shimadzu Corporation, in accordance with “JIS R1603, Method for Measuring Thermal Diffusivity, Specific Heat Capacity and Thermal Conductivity of Fine Ceramics Based on Flash Technique”. The density was measured using an in-liquid weighing technique, for example, using “AD-1653”, which is a device manufactured by A & D Company Limited, in accordance with “JIS Z8807, Method for Measuring Density and Specific Gravity of Solid”.

Also, the fracture toughness was measured, using an SEPB technique, for example, using a micrometer manufactured by Mituyo Corporation, a Vickers hardness tester HV-115 manufactured by Mituyo Corporation, a universal tester model 5582 manufactured by Instron Corporation, or MEASURESCOPE 10 manufactured by Nikon Corporation, in accordance with “JIS R1607, Method for Determining Room-Temperature Fracture Toughness of Fine Ceramics”.

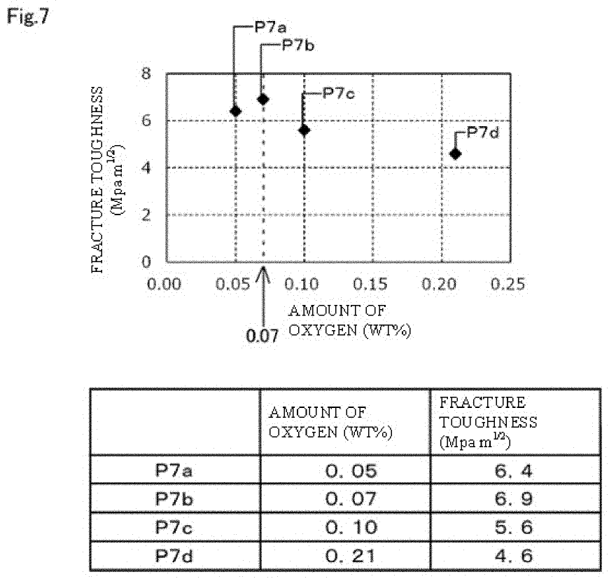

Also, the sample A is a sample having a smaller oxygen content after the degreasing process than the sample B. As is clear from the characteristic values shown in FIG. 2, the sample A has a fracture toughness of 4.0 MPam^{1/2} or more, in this case, 9.8 MPam^{1/2}. As described above, it has been confirmed that the above-described manufacturing method makes it possible to obtain a ceramic substrate 10 having an improved fracture toughness as compared with a conventional ceramic substrate containing no fibrous AlN single crystal. Also, it has been confirmed that the sample A containing a smaller amount of oxygen in its base body has a higher fracture toughness than the sample B. That is, it has been confirmed that the smaller the amount of oxygen contained in the base body 20 of the ceramic substrate 10, the higher the fracture toughness. Also, as shown in FIG. 7 to be described later, it has been confirmed that the fracture toughness tends to increase as the oxygen content decreases.

Additionally, the ceramic substrate 10 according to the present embodiment is not limited to only the samples A and B described above, and include a ceramic substrate having a thermal conductivity of 150 W/mK or more. Also, the ceramic substrate 10 according to the present embodiment includes a ceramic substrate having a fracture toughness of 4.0 MPam^{1/2} or more. Also, the ceramic substrate 10 according to the present embodiment includes a ceramic substrate having a dielectric breakdown voltage of 20 kV/mm or more.

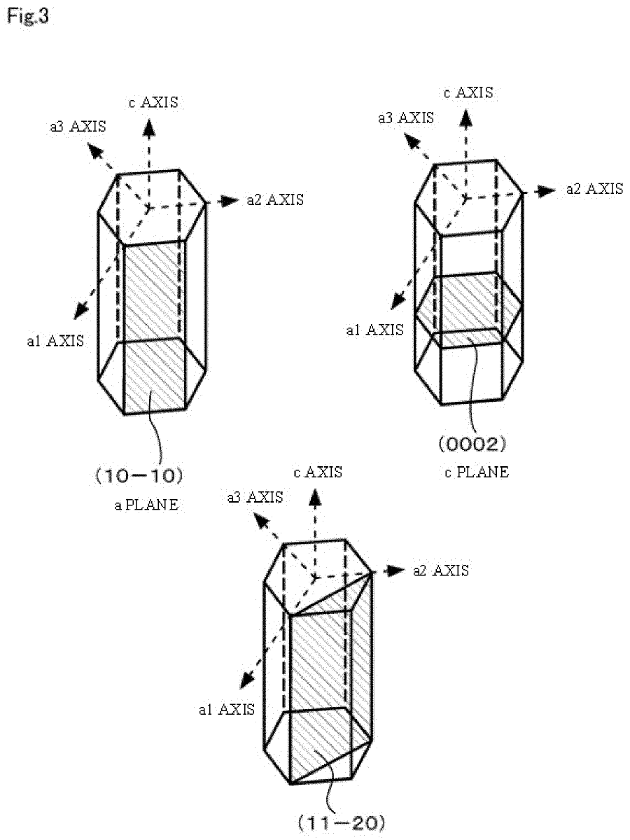

Next, the characteristics of the ceramic substrate 10 according to the present embodiment will be described in association with a structural feature of the fibrous AlN single crystal. As exemplified in FIG. 3, the fibrous AlN single crystal has a so-called hexagonal wurtzite structure as its crystal structure. Also, the fibrous AlN single crystal has a (10-10) plane, a (0002) plane, and a (11-20) plane. The (10-10) plane and the (11-20) plane are examples of “planes along a longitudinal direction of the AlN single crystal”. The (0002) plane is an example of a “plane orthogonal to the longitudinal direction of the AlN single crystal”. Hereinafter, the (10-10) plane will be referred to as “a plane”, and the (0002) plane will be referred to as “c plane”.

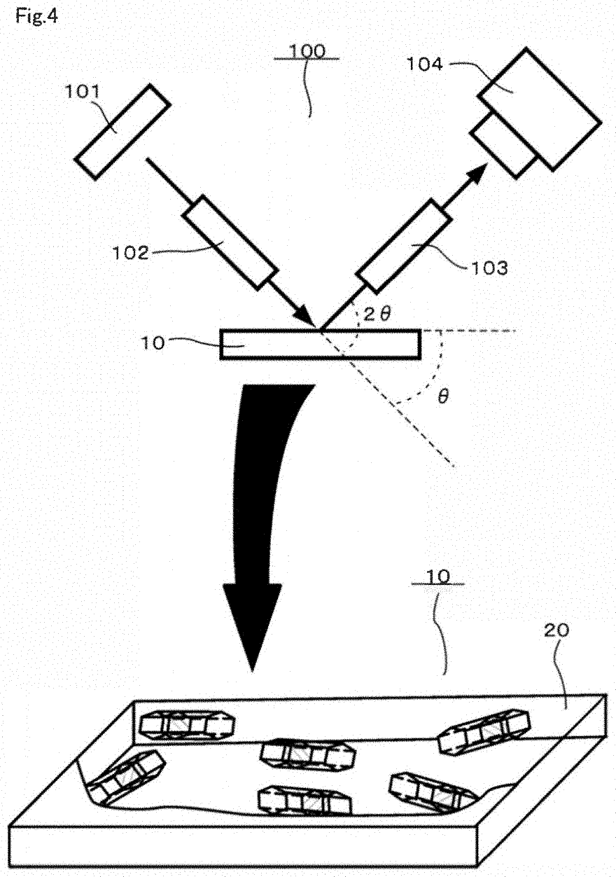

As exemplified in the lower part of FIG. 4, in the ceramic substrate 10, a large number of AlN single crystals are oriented in a direction along a surface of the base body 20 of the ceramic substrate 10, in this case, an end surface in the plate thickness direction. That is, as described above, the ceramic substrate 10 is formed into a plate shape by pressing the raw material. At this time, the long fibrous AlN single crystal is directed in a direction orthogonal to a pressing direction, that is, the plate thickness direction of the base body 20, by receiving a pressing force caused by the pressing. Therefore, in the base body 20 of the ceramic substrate 10, the fibrous AlN single crystal is directed in a direction orthogonal to the pressing direction, that is, in a direction along the end surface of the base body 20 in the plate thickness direction.

When X-ray diffraction is performed on the ceramic substrate 10 in which the fibrous AlN single crystal is oriented in the direction along the end surface of the base body 20 in the plate thickness direction as described above, the following result can be obtained. As shown in the upper part of FIG. 4, an X-ray diffraction device 100 includes an X-ray source 101 that generates an X-ray, an incident side collimator 102, a light receiving side collimator 103, and a detector 104. The X-ray generated by the X-ray source 101 is emitted to an object to be measured, in this case, the end surface of the ceramic substrate 10 in the plate thickness direction, via the incident side collimator 102. The X-ray diffracted to the object to be measured is incident on the detector 104 through the light receiving side collimator 103. Then, the detector 104 measures a diffraction pattern.

In the X-ray diffraction by the X-ray diffraction device 100, by changing a value of an angle 20 of the detector 104 with respect to a direction in which the X-ray is emitted to the object to be measured in a predetermined range, for example, in the range of 20 to 80 degrees, a diffraction peak indicating each plane of the AlN single crystal, such as “a plane” or “c plane”, can be obtained. A peak intensity obtained by X-ray diffraction is also a maximum count number for each plane, that is, the number of times each plane is present, in the AlN crystal of the ceramic substrate.

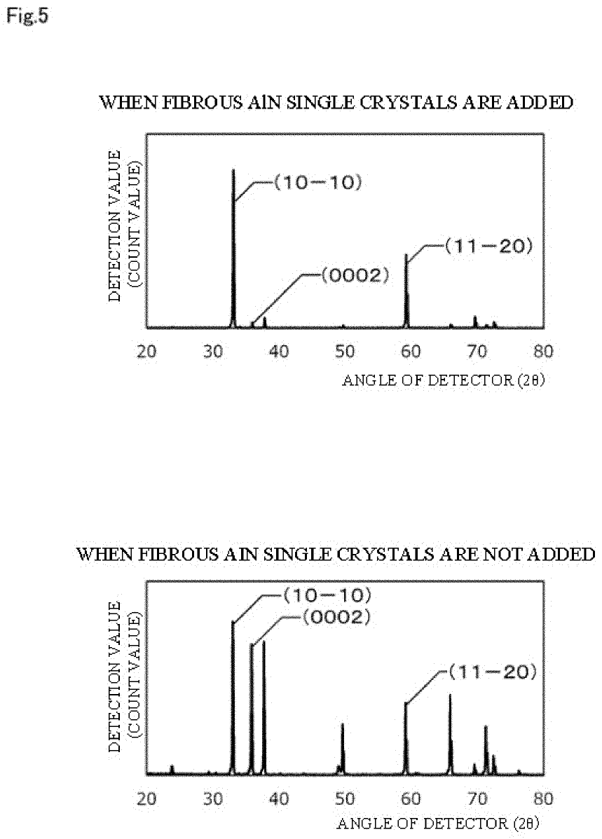

FIG. 5 shows an X-ray diffraction pattern for the ceramic substrate 10 according to the present embodiment, that is, the ceramic substrate containing a fibrous AlN single crystal in the base body 20, in comparison with an X-ray diffraction pattern for a conventional ceramic substrate, that is, a ceramic substrate containing no fibrous AlN single crystal in its base body.

That is, a peak intensity ratio indicating “a plane”, that is, (10-10) plane, in an X-ray diffraction pattern obtained when an X-ray is emitted to the end surface of the base body 20 of the ceramic substrate 10 in the plate thickness direction is larger than a peak intensity ratio indicating “a plane”, that is, (10-10) plane, in an X-ray diffraction pattern obtained when an X-ray is emitted to the end surface of the base body of the conventional ceramic substrate, which contains no fibrous AlN single crystal, in the plate thickness direction. A peak of a detection value indicating the “a plane”, that is, the (10-10) plane, is detected when the detector 104 has an angle of about 33.21 degrees. However, the peak of the detection value indicating the “a plane”, that is, the (10-10) plane, may be detected when the angle of the detector 104 is slightly deviated from about 33.21 degrees, for example, due to a shape of the sample and a positional relationship of the device.

Also, a peak intensity ratio indicating “c plane”, that is, (0002) plane, in an X-ray diffraction pattern obtained when an X-ray is emitted to the end surface of the base body 20 of the ceramic substrate 10 in the plate thickness direction is smaller than a peak intensity ratio indicating “c plane”, that is, (0002) plane, in an X-ray diffraction pattern obtained when an X-ray is emitted to the end surface of the base body of the conventional ceramic substrate, which contains no fibrous AlN single crystal, in the plate thickness direction. A peak of a detection value indicating the “c plane”, that is, the (0002) plane, is detected when the detector 104 has an angle of about 36.04 degrees. However, the peak of the detection value indicating the “c plane”, that is, the (0002) plane, may be detected when the angle of the detector 104 is slightly deviated from about 36.04 degrees, for example, due to a shape of the sample and a positional relationship of the device.

Based on such an X-ray diffraction result, in the ceramic substrate 10 according to the present embodiment, it can be confirmed that “a planes” of a large number of fibrous AlN single crystals are formed along the end surface of the base body 20 in the plate thickness direction. That is, it can be confirmed that a large number of fibrous AlN single crystals are oriented in a direction along the end surface of the base body 20 in the plate thickness direction.

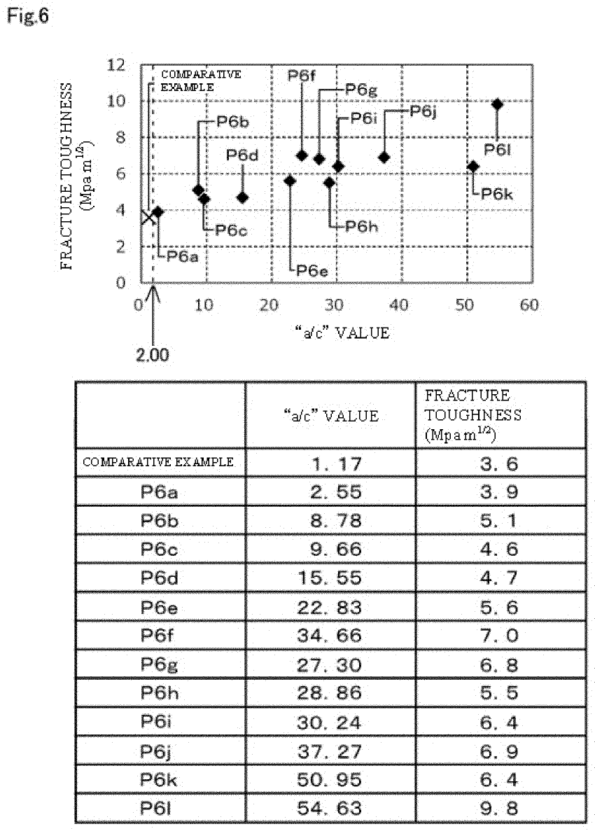

Next, a relationship between a ratio of the peak intensity for “a plane” to the peak intensity for “c plane” in the X-ray diffraction pattern obtained by the X-ray diffraction and a fracture toughness of the ceramic substrate 10 will be described. Hereinafter, a ratio of a peak intensity of a detection value for “a plane” to a peak intensity of a detection value for “c plane” will be referred to as “a/c” value. The higher the “a/c” value, the stronger the directivity of fibrous AlN single crystals contained in the base body 20 in the direction along the end surface of the base body 20 in the plate thickness direction, or the larger the abundance of fibrous AlN single crystals contained in the base body 20. That is, “a/c” values and fracture toughnesses were measured for a plurality of samples from the ceramic substrate 10 obtained by the above-described manufacturing method. As a result, as shown in FIG. 6, it has been confirmed that the fracture toughness of the ceramic substrate 10 tends to increase as the “a/c” value increases.

In particular, when the “a/c” value is 2.00 or more, it is possible to achieve a fracture toughness higher than that in the comparative example, in which no fibrous AlN single crystal is included, as indicated by points P6a, P6b, P6c, and P6d. Furthermore, when the “a/c” value is 20.00 or more, it is possible to achieve a fracture toughness much higher than that in the comparative example as indicated by points Phe, P6f, P6g, P6h, Phi, P6j, P6k, and P61. Note the “a/c” value of the ceramic substrate according to the present embodiment only needs to be larger than an “a/c” value of a conventional commercial product, for example, about 1.1, and it is possible to achieve a high fracture toughness even when the “a/c” value is 2.00 or less, for example, 1.5.

X-ray diffraction is performed by a well-known θ-2θ method, for example, using “Ultima IV”, which is a device manufactured by Rigaku Corporation, as an example of the X-ray diffraction device 100 described above. The X-ray diffraction is performed under the conditions of a voltage of 40 kV, a current of 30 mA, a divergence slit of ½ degrees, a scattering slit of ½ degrees, a light receiving slit of 0.3 mm, a scanning step of 0.02 degrees, a 20 range of 20 to 80 degrees. Regarding a peak position of an X-ray diffraction pattern, the peak position is determined based on an AlN X-ray spectrum in “AtomWork”, which is inorganic material database of National Institute for Materials Science (NIMS). Regarding a peak intensity in an X-ray diffraction pattern, a maximum count number for the peak is taken as the peak intensity.

Also, amounts of oxygen contained in plate-shaped raw materials and fracture toughnesses after the degreasing step were measured for a plurality of samples from the ceramic substrate 10 obtained by the above-described manufacturing method. As a result, as shown in FIG. 7, it has been confirmed that the fracture toughness of the ceramic substrate 10 tends to increase as the amount of oxygen contained in the base body 20 decreases. In particular, when the amount of oxygen contained in the base body 20 of the ceramic substrate 10 is 0.07 wt % or less, it is possible to achieve a high fracture toughness as indicated by points P7a and P7b.

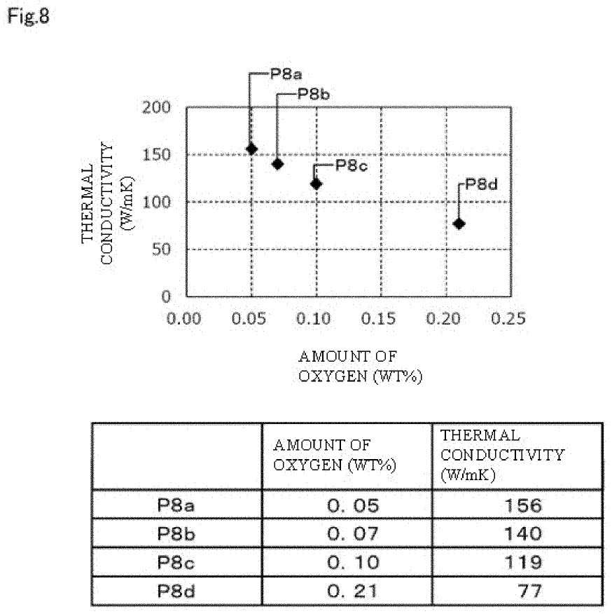

Also, amounts of oxygen contained in plate-shaped raw materials and thermal conductivities after the degreasing step were measured for a plurality of samples from the ceramic substrate 10 obtained by the above-described manufacturing method. As a result, as indicated by points P8a, P8b, P8c, and P8d in FIG. 8, it has been confirmed that the thermal conductivity of the ceramic substrate 10 tends to increase as the amount of oxygen contained in the base body 20 decreased.

The amount of oxygen was measured, for example, using a “fully automatic elemental analyzer 2400II” which is a device manufactured by PerkinElmer. The amount of oxygen was measured as follows. That is, a holder made of tin was filled with an about 5 mg of sample, and was put into the device. Then, the sample was decomposed by thermal decomposition, and oxygen was brought into reaction with carbon monoxide using a carbon catalyst to perform analysis.

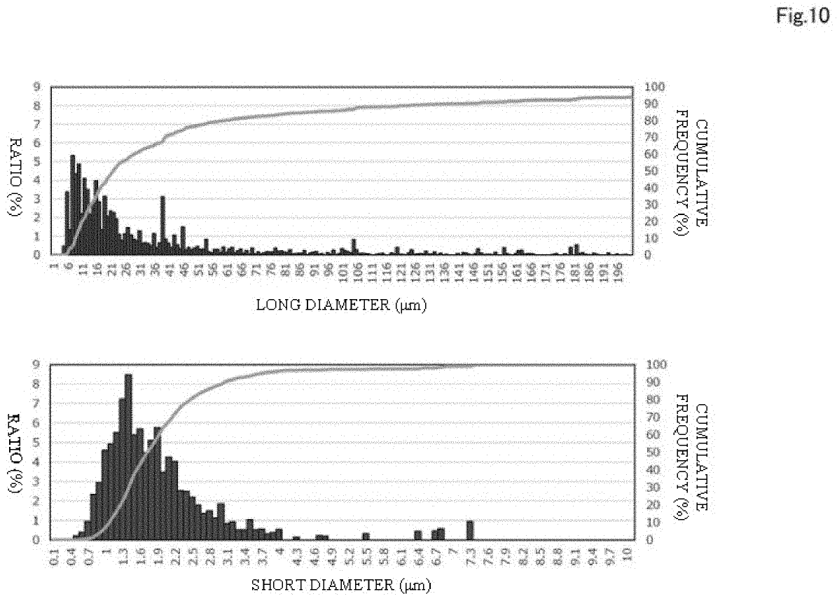

In the ceramic substrate 10 according to the present embodiment, fibrous AlN single crystals put in the kneading step have different lengths. That is, as shown in the upper part of FIG. 10, the base body 20 of the ceramic substrate 10 contains a plurality of AlN single crystals having different long diameters, that is, different lengths. For example, 50 vol % of the plurality of AlN single crystals contained in the base body 20 are longer than 20 Also, 10 vol % of the plurality of AlN single crystals contained in the base body 20 are longer than 134 μm.

Also, in the ceramic substrate 10 according to the present embodiment, fibrous AlN single crystals put in the kneading step have different thicknesses in the range of about 1 to 10 μm. That is, as shown in the lower part of FIG. 10, the base body 20 of the ceramic substrate 10 contains a plurality of AlN single crystals having different short diameters, that is, different thicknesses. For example, 50 vol % of the plurality of AlN single crystals contained in the base body 20 are thicker than 1.6 μm. Also, 10 vol % of the plurality of AlN single crystals contained in the base body 20 are thicker than 2.9 μm.

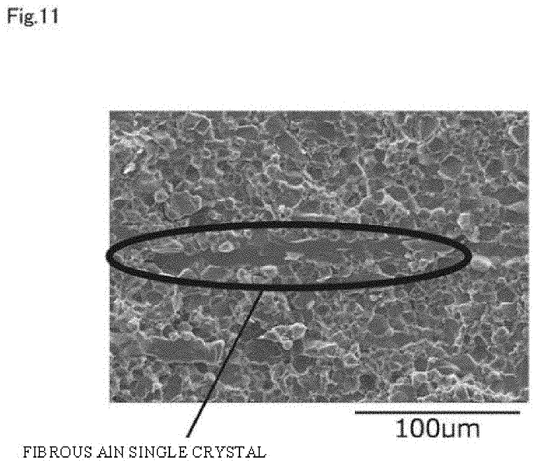

Also, the fibrous AlN single crystals to be put in the kneading step are preferably longer than 10 μm, and more preferably longer than 15 μm. Additionally, the ceramic substrate 10 according to the present embodiment preferably contains fibrous AlN single crystals in a non-broken state if possible. Also, in the ceramic substrate 10 according to the present embodiment, for example, when fibrous AlN single crystals longer than 100 μm are used in the kneading step, the fibrous AlN single crystals longer than 100 μm actually exist in the base body 20 even after the sintering step as shown in FIG. 11. The method for manufacturing the ceramic substrate 10 according to the present embodiment has a best feature in that the fibrous AlN single crystals put in the kneading step actually exist in the base body 20 after the sintering step in a state where their lengths are not impaired.

As a result of testing a plurality of samples from the ceramic substrate 10 according to the present embodiment, it has been confirmed that when the AlN single crystals contained in the base body 20 of the ceramic substrate 10 have a length of 10 μm or more in any length ratio, it is possible to obtain a fracture toughness higher than that of a conventional ceramic substrate, regardless of an AlN single crystal content, as long as the AlN single crystals are fibrous. Also, it has been confirmed that when the AlN single crystals contained in the base body 20 of the ceramic substrate 10 have a thickness in the range of 1 to 10 μm, it is possible to obtain a fracture toughness higher than that of a conventional ceramic substrate, regardless of an AlN single crystal content, as long as the AlN single crystals are fibrous.

Here, a surface of the AlN single crystal contained in the ceramic substrate is preferably covered with an oxygen-containing layer from the viewpoint of improvement in water resistance and the like. The oxygen-containing layer is formed by the AlN single crystal incorporating at least oxygen atoms in a process of preparing the AlN single crystal. When AlN reacts with oxygen molecules or water molecules, an oxygen-containing layer including at least one of Al₂O₃, AlON, and Al(OH)₃ may be formed to cover the surface of the AlN single crystal. However, from the viewpoint of improvement in water resistance, the oxygen-containing layer preferably includes AlON.

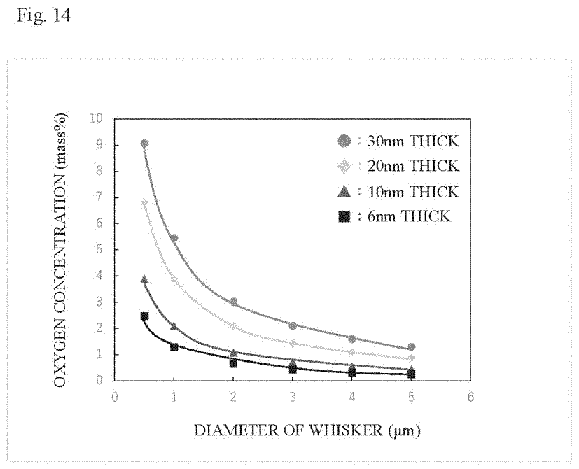

When what includes an AlN single crystal and an oxygen-containing layer covering a surface of the AlN single crystal is referred to as an “AlN whisker”, an oxygen concentration in the AlN whisker (corresponding to a concentration of the oxygen-containing layer) is preferably 7.0 mass % or less, more preferably 4.0 mass % or less, and most preferably 2.0 mass % or less. This is based on the fact that, as shown in FIG. 14, as a result of testing a plurality of AlN whiskers used in the present embodiment, it has been found that there is a correlation between an oxygen concentration in the AlN whisker and a diameter (thickness) of the AlN whisker depending on what thickness an oxygen-containing layer has among various thicknesses (6 nm, 10 nm, 20 nm, 30 nm). That is, as described above, the AlN single crystals preferably have a diameter (thickness) of 1 μm or more in order to improve the fracture toughness of the ceramic substrate 10. In this regard, referring to FIG. 14, it is seen that, in order to set the diameter of the AlN whisker (in this description, for convenience, it is assumed that the diameter of the AlN whisker is substantially the same as the diameter of the AlN single crystal) to 1.0 μm or more, the oxygen concentration is preferably 7.0 mass % or less, more preferably 4.0 mass % or less, and most preferably 2.0 mass % or less.

Also, the ceramic substrate 10 contains a plurality of (a large number of) AlN whiskers (AlN single crystals). That is, in the kneading step described above, a plurality of (a large number of) AlN whiskers (AlN single crystals) are dispersed in the mixed liquid of the dispersion material and the organic solvent. Here, when the plurality of AlN whiskers dispersed in the mixed liquid is collectively referred to as an “AlN whisker composite” for convenience, the plurality of AlN whiskers (the plurality of AlN single crystals) having different diameters (thicknesses) are included in the AlN whisker composite. Here, as described above, the AlN whiskers preferably have a diameter of 1.0 μm or more. Referring to FIG. 10 as an example of a ratio thereof, a content ratio of the AlN whiskers having a diameter of less than 1.0 μm in the AlN whisker composite is preferably 20 vol % or less (a content ratio of the AlN whiskers having a diameter of 1.0 μm or more is 80 vol % or more).

Analysis data regarding lengths (long diameters in FIG. 10) and thicknesses (short diameters in FIG. 10) of AlN single crystals shown in FIG. 10 was acquired, by placing the AlN single crystals contained in the ceramic substrate 10 according to the present embodiment into “PITA-04”, which is a device for analyzing a particle shape image manufactured by Seishin Enterprise Co., Ltd. The analysis data shown in FIG. 10 is obtained, for example, by preparing and analyzing about 5000 AlN single crystals.

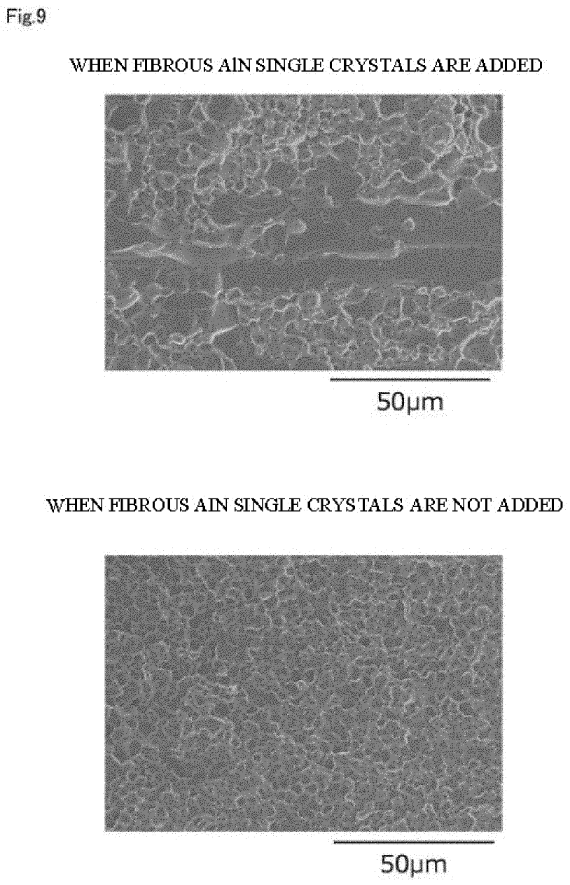

As exemplified in FIG. 9, the conventional ceramic substrate has a structure including particles of about 2 to 3 μm. On the other hand, the ceramic substrate 10 according to the present embodiment has a characteristic structure in which three kinds of substances, i.e. fibrous AlN single crystals, particles of about 2 to 3 μm, and particles of about 10 μm, are mixed.

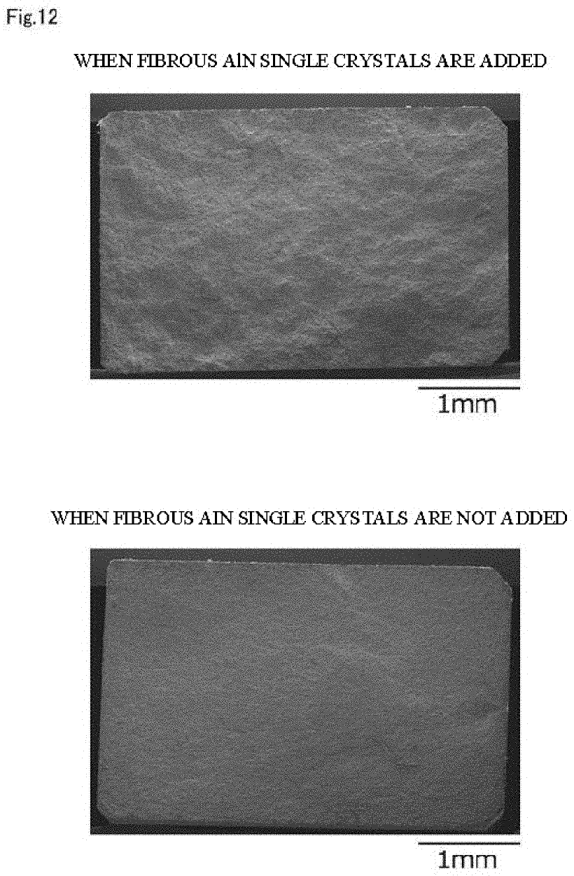

Also, as illustrated in FIG. 12, in the ceramic substrate 10 according to the present embodiment, when the base body 20 containing fibrous AlN single crystals is fractured in a fracture toughness test, a fractured surface of the base body 20 is a non-smooth surface having a large number of irregularities. That is, the base body 20 of the ceramic substrate 10 according to the present embodiment contains not only “granular” AlN polycrystals but also a large number of “fibrous” AlN single crystals. Therefore, after the fracture toughness test, the fractured surface of the base body 20 is in a bent state particularly at a portion where the fibrous AlN single crystals exist, and as a result, the fractured surface of the base body 20 is a non-smooth surface having a large number of irregularities as compared with the conventional ceramic substrate.

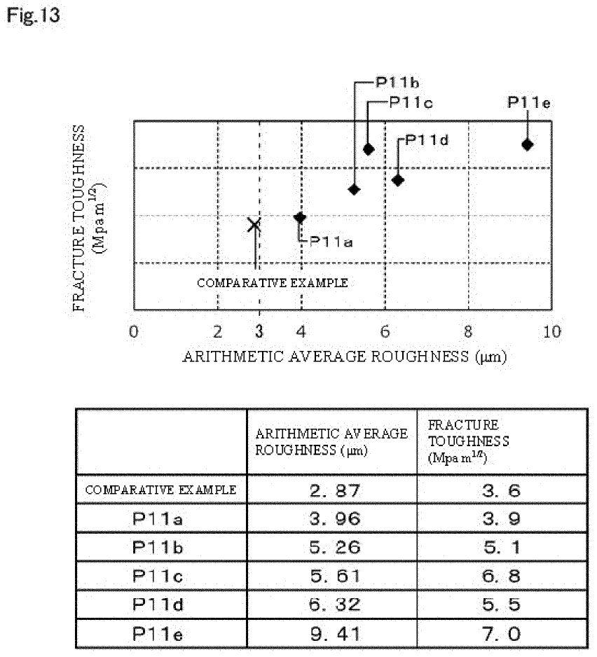

As indicated by points P11a, P11b, P11_{c}, P11d, and P11e in FIG. 13, as a result of testing a plurality of samples from the ceramic substrate 10 according to the present embodiment, it has been confirmed that the fracture toughness of the ceramic substrate 10 tends to decrease as the arithmetic average roughness of the fractured surface of the base body 20 decreases, and the fracture toughness of the ceramic substrate 10 tends increase as the arithmetic average roughness of the fractured surface of the base body 20 increases. In particular, when the arithmetic average surface roughness of the fractured surface of the base body 20 is 3 μm or more, it is possible to achieve a fracture toughness higher than that in the comparative example, in which no fibrous AlN single crystal is included. That is, the high arithmetic average roughness of the fractured surface means that a propagation direction of a crack formed in the structure of the base body 20 when fractured is irregular, and therefore, it is considered that a high fracture toughness is achieved on the basis of such characteristics. Therefore, it can be said that the base body 20 having a higher fracture toughness has a larger number of irregularities formed on the fractured surface thereof, and the fracture surface has a higher arithmetic average roughness.

A surface height of the fractured surface was measured by a known height measurement method, for example, using “OPTELICSH1200”, which is a device manufactured by Lasertec Inc. The surface height of the fractured surface was measured under the conditions of a lens magnification of 50 times and a resolution of 0.01 The arithmetic average roughness was determined in an arbitrary square of 300 μm on the ceramic substrate in accordance with “JIS B0601, Geometric Property Specifications (GPS) of Product—Surface Property: Contour Curve Method—Terms, Definitions and Surface Property Parameters”.

According to the ceramic substrate 10 according to the present embodiment exemplified above, the base body 20 constituting a main body portion thereof has a structure in which a large number of fibrous AlN single crystals are oriented in a direction along the end surface of the base body 20 in the plate thickness direction. According to the ceramic substrate 10 having such a structure, the presence of the fibrous AlN single crystals makes it possible to further improve thermal conductivity as compared with that of the conventional ceramic substrate, and also, further improve fracture toughness, that is, further improve mechanical strength, as compared with that of the conventional ceramic substrate.

Also, the improvement in fracture toughness, that is, mechanical strength, makes it possible to reduce a plate thickness of the ceramic substrate 10. Therefore, heat generated from the power semiconductor 12 can be more easily transferred to the heat sink 13, thereby further improving heat dissipation performance.

As described above, according to the present embodiment, the ceramic substrate 10 having both high thermal conductivity and high mechanical strength can be obtained.

The characteristics of the ceramic substrate 10 exemplified in the present embodiment have similar tendencies even when a detection value indicating “a plane along a longitudinal direction of an AlN single crystal” such as a (11-20) plane is used instead of the detection value indicating the (10-10) plane obtained by X-ray diffraction. A peak of the detection value indicating the (11-20) plane is detected when the detector 104 has an angle of about 59.34 degrees. However, the peak of the detection value indicating the (11-20) plane may be detected when the angle of the detector 104 is slightly deviated from about 59.34 degrees, for example, due to a shape of the sample and a positional relationship of the device.

The present embodiment exemplified above represents one embodiment for a ceramic substrate and an AlN crystal, an AlN whisker, and an AlN whisker composite contained in the ceramic substrate, and various modifications and extensions can be made without departing from the gist thereof. For example, the ceramic substrate containing a fibrous AlN single crystal in its base body may be specified by a parameter different from a thermal conductivity, a fracture toughness, a diffraction pattern of X-ray diffraction, and an amount of oxygen contained in the base body.

In the present disclosure, a numerical range suggested using the expression “to” indicates a range including numerical values described before and after the term “to” as a minimum value and a maximum value, respectively.

The present disclosure is based upon and claims the benefit of priority from the following Japanese patent application. The disclosure of the following Japanese patent application is incorporated herein in its entirety by reference.

(1) Japanese Patent Application No. 2020-134777, titled “CERAMIC SUBSTRATE” and filed on Aug. 7, 2020.

1. A ceramic substrate comprising a fibrous AlN single crystal in a base body thereof.

2. The ceramic substrate of claim 1, wherein the ceramic substrate has a thermal conductivity of 150 W/mK or more and a fracture toughness of 4.0 MPam^{1/2} or more.

3. The ceramic substrate of claim 1, wherein the fibrous AlN single crystal has a hexagonal wurtzite structure, and
a ratio of a (10-10) plane peak intensity to a (0002) plane peak intensity of the AlN single crystal obtained when an X-ray is emitted to an end surface of the base body in a plate thickness direction is 2.00 or more.

4. The ceramic substrate of claim 1, wherein an amount of oxygen contained in the base body is 0.07 wt % or less.

5. The ceramic substrate of claim 1, wherein a fractured surface of the base boy containing the AlN single crystal has an arithmetic average roughness of 3 μm or more.

6. The ceramic substrate of claim 1, wherein the base body further contains a granular AlN single crystal.

7. A ceramic substrate comprising an AlN whisker in a base body thereof, the AlN whisker including a fibrous AlN single crystal having a hexagonal wurtzite structure and an oxygen-containing layer covering a surface of the AlN single crystal, wherein an oxygen concentration is 7.0 mass % or less.

8. A ceramic substrate comprising an AlN whisker composite including a plurality of AlN whiskers in a base body thereof, each of the plurality of AlN whiskers including a fibrous AlN single crystal having a hexagonal wurtzite structure and an oxygen-containing layer covering a surface of the AlN single crystal, wherein a content ratio of AlN whiskers having a diameter of less than 1.0 μm is 20 vol % or less.

9. A fibrous AlN single crystal having a hexagonal wurtzite structure, wherein a ratio of a (10-10) plane peak intensity to a (0002) plane peak intensity obtained when an X-ray is emitted to an end surface in a plate thickness direction is 2.00 or more.

10. An AlN whisker comprising a fibrous AlN single crystal having a hexagonal wurtzite structure and an oxygen-containing layer covering a surface of the AlN single crystal, wherein an oxygen concentration is 7.0 mass % or less.

11. An AlN whisker composite comprising a plurality of AlN whiskers, each of the plurality of AlN whiskers including a fibrous AlN single crystal having a hexagonal wurtzite structure and an oxygen-containing layer covering a surface of the AlN single crystal, wherein a content ratio of AlN whiskers having a diameter of less than 1.0 μm is 20 vol % or less.
